(19) United States
(12) Patent Application Publication
(10) Pub. No.: US 2025/0136761 A1
(43) Pub. Date: May 1, 2025

(54) MODIFIED BISMALEIMIDE PREPOLYMER, RESIN COMPOSITION AND APPLICATION OF RESIN COMPOSITION

(71) Applicants: SHENGYI TECHNOLOGY (SUZHOU) CO., LTD, Suzhou, Jiangsu (CN); SHENGYI TECHNOLOGY (CHANGSHU) CO., LTD, Suzhou, Jiangsu (CN)

(72) Inventors: Chunmei CUI, Suzhou (CN); Feng JIAO, Suzhou (CN); Hui WANG, Suzhou (CN); Xiangxiu CHEN, Suzhou (CN); Tiekuang DING, Suzhou (CN)

(73) Assignees: SHENGYI TECHNOLOGY (SUZHOU) CO., LTD, Suzhou, Jiangsu (CN); SHENGYI TECHNOLOGY (CHANGSHU) CO., LTD, Suzhou, Jiangsu (CN)

(21) Appl. No.: 18/836,973

(22) PCT Filed: Mar. 31, 2023
(86) PCT No.: PCT/CN2023/085349

§ 371 Date: Aug. 8, 2024

(30) Foreign Application Priority Data
Oct. 11, 2022 (CN) 202211240716.X
Oct. 11, 2022 (CN) 202211241822.X
Oct. 11, 2022 (CN) 202211241857.3

(51) Int. Cl. C08G 73/12; C08L 79/08

(52) U.S. Cl. CPC C08G 73/125; C08L 79/085; C08L 2205/03

(57) ABSTRACT

The present invention provides a modified bismaleimide prepolymer, a resin composition and application thereof. The modified bismaleimide prepolymer is obtained by a reaction of a bismaleimide compound with an amino organosilicone resin A and an amino organosilicone resin B, where the amino equivalent (Ea_{A}) of the amino organosilicone resin A is different from the amino equivalent (Ea_{B}) of the amino organosilicone resin B, and the ratio of the total mass of the amino organosilicone resin A and the amino organosilicone resin B to the mass of the bismaleimide compound is (5-80):100. According to the present invention, the reactivity of the bismaleimide compound is improved, and the rheological property of the modified bismaleimide prepolymer applied in the field of substrate materials such as packaging substrates during lamination at high temperature is controlled.

The present application claims the priority to the Chinese Patent Application having an application date of Oct. 11, 2022, an application number of 202211240716.X, and a title of “MODIFIED BISMALEIMIDE PREPOLYMER, RESIN COMPOSITION AND USE OF RESIN COMPOSITION”, which is incorporated herein by reference in its entirety.

### TECHNICAL FIELD

The present invention relates to the technical field of electronic materials, and in particular to a modified bismaleimide prepolymer, a resin composition containing the modified bismaleimide prepolymer and application of the resin composition.

### BACKGROUND

In recent years, miniaturized and high-performance electronic equipment has been developed, and high-density and high-concentration of wiring density in printed circuit boards have been constantly developed. Thus, higher requirements for the heat resistance and reliability of copper clad laminates have been put forward. In particular, in semiconductor packaging substrates, the problem of warping is caused by differences of the thermal expansion rate between chips and organic substrates during packaging and assembling.

Bismaleimide resin cured substances have high temperature resistance, humidity and heat resistance, high modulus, low CTE value, high strength and other excellent performances, thereby being especially suitable for serving as matrix resins of IC packaging carrier plates and similar carrier plates. However, the bismaleimide resin cured substances also have high brittleness, poor processing performance and other defects, thereby being limited in large-scale application.

In the prior art, in order to improve the above problems of the bismaleimide resin cured substances, a silicone rubber powder is introduced into bismaleimide resins. Due to the introduction of the silicone rubber powder, the water absorption and toughness of the bismaleimide resin cured substances are improved to a certain extent. However, due to low density, easy agglomeration and poor dispersion, the silicone rubber powder floats on an upper layer of a bismaleimide resin glue solution to form phase separation, leading to layering of the bismaleimide resin cured substances and other problems. In addition, silicone oil is also directly added to the bismaleimide resins in the prior art. However, during lamination of the cured substances, the silicone oil is extremely likely to leak out of the system in an incomplete reaction, so that the production processability is affected, and comprehensive performance of final cured substances is seriously affected.

### SUMMARY

The purpose of the present invention is to provide a modified bismaleimide prepolymer, a resin composition containing the modified bismaleimide prepolymer and application of the resin composition. The modified bismaleimide prepolymer is modified by a reaction of a bismaleimide compound with different amino equivalents of amino organosilicone resins, and the mass of the amino organosilicone resins and the bismaleimide compound is controlled, so that not only is the problem of high brittleness of a bismaleimide resin improved, but also the reactivity of the bismaleimide resin and the rheological property of the resin during lamination at high temperature are better controlled, thereby improving the processing performance of the resin composition.

To achieve one of the above objects, an implementation of the invention provides a modified bismaleimide prepolymer, which is obtained by a reaction of a bismaleimide compound with an amino organosilicone resin A and an amino organosilicone resin B, the amino equivalent (Ea_{A}) of the amino organosilicone resin A is different from the amino equivalent (Ea_{B}) of the amino organosilicone resin B, and the ratio of the total mass of the amino organosilicone resin A and the amino organosilicone resin B to the mass of the bismaleimide compound is (5-80):100.

As a further improvement of an implementation of the invention, the ratio of the total mass of the amino organosilicone resin A and the amino organosilicone resin B to the mass of the bismaleimide compound is (20-50):100.

As a further improvement of an implementation of the invention, the mass ratio of the amino organosilicone resin A to the amino organosilicone resin B is 1:(2-30).

As a further improvement of an implementation of the invention, both the amino organosilicone resin A and the amino organosilicone resin B have the following structure:

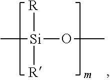

wherein both R and R′ are C1-C5 alkyl, and m is an integer ranging from 1 to 30.

As a further improvement of an implementation of the invention, a side chain of the amino organosilicone resin A and/or the amino organosilicone resin B contains at least one amino.

As a further improvement of an implementation of the invention, a terminal end of the amino organosilicone resin A and/or the amino organosilicone resin B contains at least one amino.

An implementation of the invention further provides a resin composition which comprises, by weight, the following components:
(a) 30-100 parts of a modified bismaleimide prepolymer,
(b) 3-50 parts of a cyanate resin, and
(c) 5-60 parts of an elastomer,
where the modified bismaleimide prepolymer is the modified bismaleimide prepolymer described above.

As a further improvement of an implementation of the invention, the cyanate resin is selected from one or more of a bisphenol A cyanate resin, a bisphenol F cyanate resin, a bisphenol S cyanate resin, a bisphenol E cyanate resin, a bisphenol M cyanate resin, a cyanate resin containing a double bond, a phosphorus-containing cyanate resin, a phenolic cyanate resin, a biphenyl cyanate resin, a naphthalene ring cyanate resin and a dicyclopentadiene cyanate resin.

As a further improvement of an implementation of the invention, the cyanate resin is a naphthalene ring cyanate resin or/and a phenolic cyanate resin having the following structure:

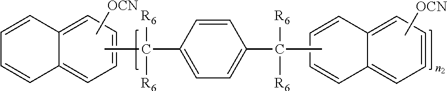

structural formula (1), wherein R₆ is hydrogen, methyl or ethyl, and n₂ is an integer ranging from 1 to 10;
or

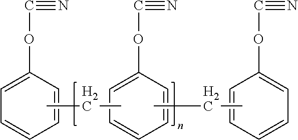

structural formula (2), wherein n is an integer ranging from 1 to 10.

As a further improvement of an implementation of the invention, the elastomer is selected from at least one of a styrene elastomer, a methacrylate elastomer and an organosilicone elastomer.

As a further improvement of an implementation of the invention, the resin composition further comprises a silane coupling agent and a dispersing agent.

As a further improvement of an implementation of the invention, the silane coupling agent is an epoxy silane coupling agent, the dispersing agent is a phosphate dispersing agent and/or a modified polyurethane dispersing agent, and the weight ratio of the silane coupling agent to the dispersing agent is 2:1 to 10:1.

An implementation of the invention further provides application of the resin composition described above in a semi-cured sheet, a laminate board, an insulating film, an insulating board, a copper clad laminate, a circuit substrate and an electronic device.

One or more of technical solutions provided by the present invention have at least the following technical effects or advantages.

According to the modified bismaleimide prepolymer provided by the present invention, by enabling a reaction of the bismaleimide compound with different amino equivalents of the amino organosilicone resins, the reactivity and brittleness of the bismaleimide compound are improved. Meanwhile, by controlling the mass of the amino organosilicone resins and the bismaleimide compound, the rheological reaction window of the resin composition is better regulated, and the risk of defects such as dry patterns or white cracks on a base material due to a rapid reaction during pressing of the resin composition is reduced.

### BRIEF DESCRIPTION OF THE DRAWINGS

FIG. 1 is a diagram showing rheological curves of Example 2 and Comparative Example 2 of the present invention.

### DETAILED DESCRIPTION

The present invention is described in detail below in combination with specific embodiments, but the present invention is not limited to these embodiments. All changes of reaction conditions, reactants or amounts of raw materials made by those ordinary persons skilled in the art according to these embodiments are included in the protection scope of the present invention.

An example of the present invention provides a modified bismaleimide prepolymer. The modified bismaleimide prepolymer is obtained by a reaction of a bismaleimide compound with an amino organosilicone resin A and an amino organosilicone resin B, where the amino equivalent (Ea_{A}) of the amino organosilicone resin A is different from the amino equivalent (Ea_{B}) of the amino organosilicone resin B, and the ratio of the total mass of the amino organosilicone resin A and the amino organosilicone resin B to the mass of the bismaleimide compound is (5-80):100.

Preferably, the ratio of the total mass of the amino organosilicone resin A and the amino organosilicone resin B to the mass of the bismaleimide compound is (20-50):100.

Further, the mass ratio of the amino organosilicone resin A to the amino organosilicone resin B is 1:(2-30).

The reaction of the bismaleimide compound with the amino organosilicone resin A and the amino organosilicone resin B is specifically as follows:
the bismaleimide compound is reacted with the amino organosilicone resin A at 60-90° C. for 0.5-1.5 hours firstly, the temperature is raised to 90-130° C., and then the amino organosilicone resin B is added, the reaction is carried out continuously for 0.5-2 hours.

Preferably, 0.1-10 parts by weight of at least one of aminophenol, carboxylic acid or carboxylic anhydride is added in the reaction process, and a phenolic hydroxyl group, a carboxylic group or an anhydride group in the aminophenol, the carboxylic acid or the carboxylic anhydride can react with the bismaleimide compound so as to improve the reactivity.

Further, the amino equivalent (Ea_{A}) of the amino organosilicone resin A is equal to or greater than 100 g/mol and equal to or less than 500 g/mol, and the amino equivalent (Ea_{B}) of the amino organosilicone resin B is equal to or greater than 500 g/mol and equal to or less than 1,600 g/mol.

Preferably, the absolute value of the amino equivalent difference of the organosilicone resin A and the organosilicone resin B is 100-600 g/mol.

Both the amino organosilicone resin A and the amino organosilicone resin B have the following structure:

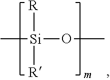

where both R and R′ are C1-C5 alkyl, and m is an integer ranging from 1 to 30.

Further, a side chain of the amino organosilicone resin A and/or the amino organosilicone resin B contains at least one amino.

Further, a terminal end of the amino organosilicone resin A and/or the amino organosilicone resin B contains at least one amino.

Further, the bismaleimide compound may be selected from at least one of the following in structures:

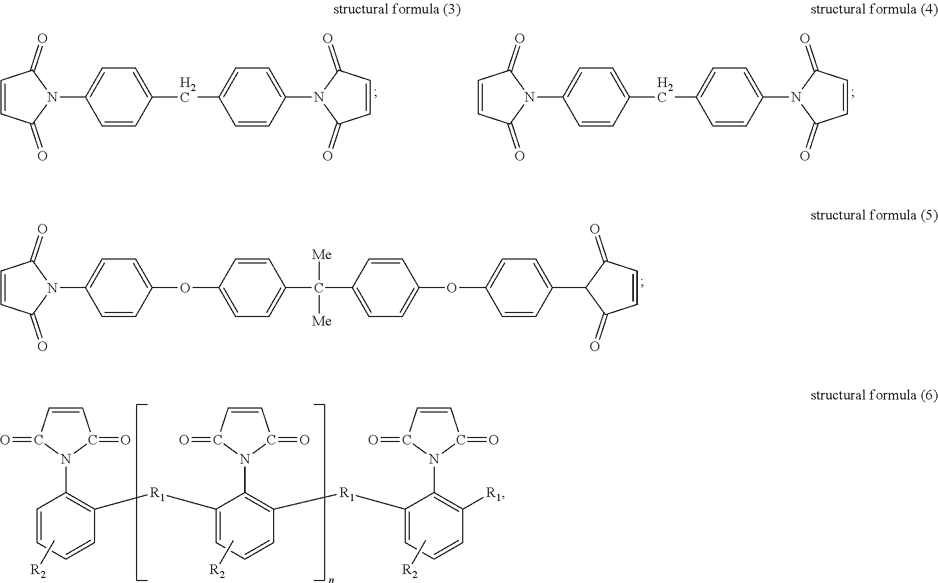

where R₂ is hydrogen, methyl or ethyl, R₁ is methylene or ethylidene, and n is an integer ranging from 1 to 10;

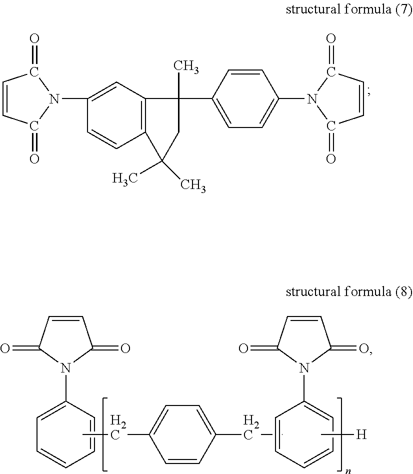

where n is an integer ranging from 1 to 10;

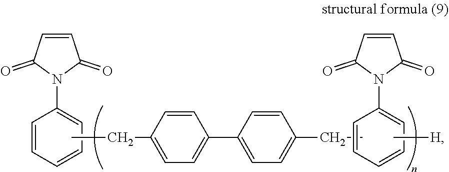

where n is an integer ranging from 1 to 10;

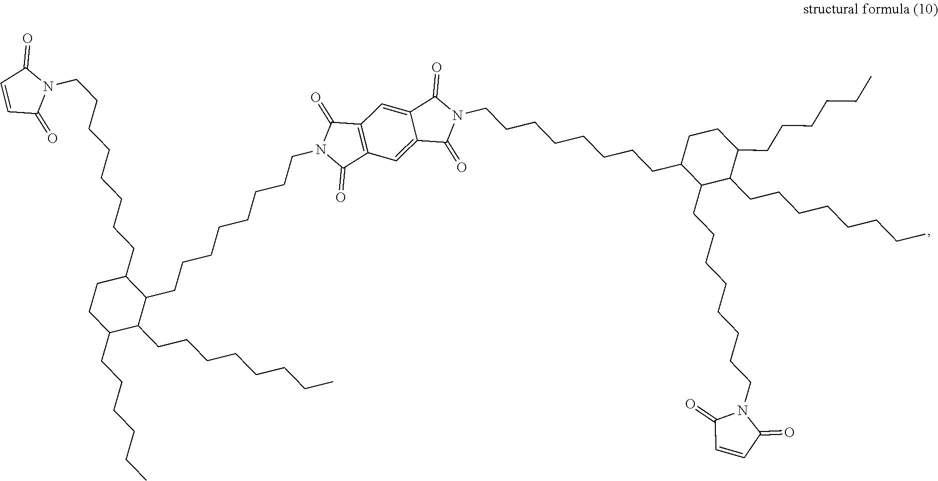

where n is an integer ranging from 1 to 10;

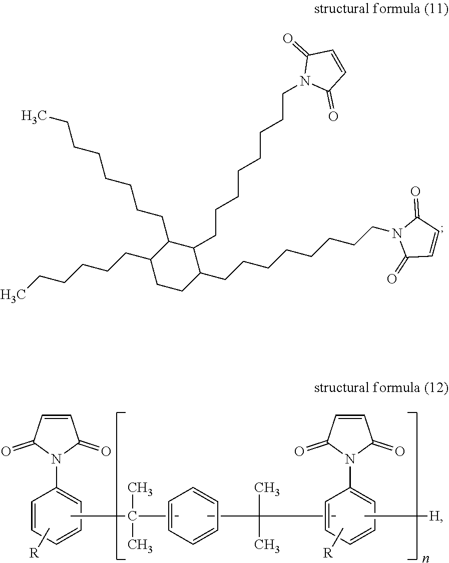

where R is hydrogen, methyl or ethyl, and n is an integer ranging from 1 to 10.

The present invention further provides a resin composition. The resin composition includes, by weight, the following components:
(a) 30-100 parts of a modified bismaleimide prepolymer,
(b) 3-50 parts of a cyanate resin, and
(c) 5-60 parts of an elastomer,
where the modified bismaleimide prepolymer is the modified bismaleimide prepolymer described above.

Further, the cyanate resin is selected from one or more of a bisphenol A cyanate resin, a bisphenol F cyanate resin, a bisphenol S cyanate resin, a bisphenol E cyanate resin, a bisphenol M cyanate resin, a cyanate resin containing a double bond, a phosphorus-containing cyanate resin, a phenolic cyanate resin, a biphenyl cyanate resin, a naphthalene ring cyanate resin and a dicyclopentadiene cyanate resin.

Preferably, the cyanate resin is a naphthalene ring cyanate resin or/and a phenolic cyanate resin having the following structure:

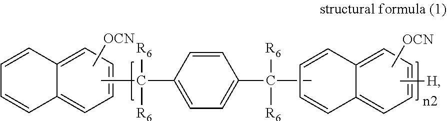

where R₆ is hydrogen, methyl or ethyl, and n₂ is an integer ranging from 1 to 10;
or

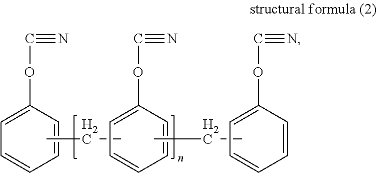

where n is an integer ranging from 1 to 10.

Further, the elastomer is selected from at least one of a styrene elastomer, a methacrylate elastomer and an organosilicone elastomer.

The styrene elastomer is selected from H1041, H1043, H1051, H1052, H1053, H1221, P1500, P2000, M1911 or M1913 made by Asahi Kasei of Japan, or 8004, 8006, 8076, 8104, V9827, 2002, 2005, 2006, 2007, 2104, 7125, 4033, 4044, 4055, 4077 or 4099 made by Kuraray.

The methacrylate elastomer is selected from M51, M52, M22 or D51N made by Arkema, LA-2330 made by Kuraray, or SG-P3 series or SG-80 series made by Nagase.

The organosilicone elastomer is selected from X-40-2670, R-170S, X-40-2705, X-40-2701, KMP-600, KMP-605 and X-52-7030 made by Shin-Etsu Chemical, or AY-42-119, EP-2600, EP-2601, EP-2720, TMS-2670, EXL-2315, EXL-2655 and the like made by DOW.

Further, the resin composition further includes 0.01-5 parts by weight of a catalyst, and the catalyst is at least one of an imidazole catalyst, a pyridine catalyst and an organometallic salt catalyst. Preferably, the catalyst is at least one of 4-dimethylaminopyridine, 2-methylimidazole, 2-methyl-4-ethylimidazole, 2-phenylimidazole, modified imidazole and zinc caprylate.

The modified imidazole has the following structure:

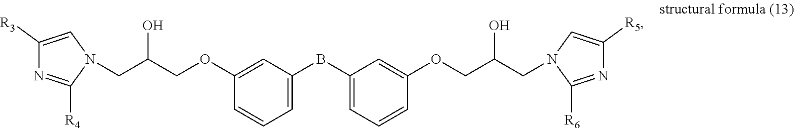

where R₃, R₄, R₅ and R₆ are the same or different and are methyl, ethyl or tert-butyl respectively, B is methylene, ethylidene,

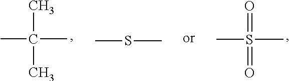

and P200F50 made by JER can be used;
or

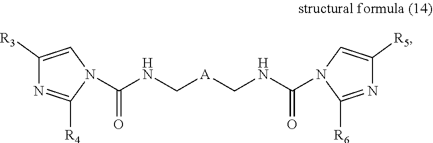

where R₃, R₄, R₅ and R₆ are the same or different, and are methyl, ethyl or tert-butyl respectively, A is methylene, ethylidene,

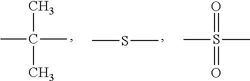

or an aromatic hydrocarbon group, and G8009L made by the first industry can be used.

Further, the resin composition further includes 20-200 parts by weight of a filler. The filler includes an inorganic filler, an organic filler or a composite filler. The inorganic filler is selected from at least one of molten silica, crystalline silica, spherical silica, hollow silica, aluminum hydroxide, alumina, talc powder, aluminum nitride, boron nitride, silicon carbide, barium sulfate, barium titanate, strontium titanate, calcium carbonate, calcium silicate, mica and glass fiber powder. The organic filler is selected from at least one of polytetrafluoroethylene powder, polyphenylene sulfide powder and polyether sulfone powder.

Preferably, the filler is spherical silica, alumina or aluminum hydroxide, and is more preferably spherical silica.

Preferably, the content of the filler is 30-150 parts by weight.

Further, the filler is subjected to surface treatment with a silane coupling agent, and the silane coupling agent is at least one of an amino silane coupling agent, a silane coupling agent containing a carbon-carbon double bond or an epoxy silane coupling agent. Preferably, the silane coupling agent is selected from one or more of the following brands: KBM-573 made by Shin-Etsu Chemical, Z-6883 made by Dow Corning, KBM-1003 made by Shin-Etsu Chemical and KBM-1403 made by Shin-Etsu Chemical.

Further, the resin composition further includes a silane coupling agent and a dispersing agent, the silane coupling agent is an epoxy silane coupling agent, the dispersing agent is a phosphate dispersing agent and/or a modified polyurethane dispersing agent, and the weight ratio of the silane coupling agent to the dispersing agent is 2:1 to 10:1.

Further, based on 100 parts by weight of the resin composition, the resin composition further includes 5-50 parts by weight of a flame retardant, and the flame retardant is selected from a bromine flame retardant, a phosphorus flame retardant, a nitrogen flame retardant, an organosilicone flame retardant, an organometallic salt flame retardant and the like.

Preferably, the flame retardant is selected from the following brands: SPB-100 phosphonitrile made by Otsuka Chemical of Japan, or BP-PZ, PP-PZ, SPCN-100, SPV-100 and SPB-100L modified polyphosphazene.

Further, a dye including a fluorescent dye or a black dye may also be added to the resin composition. The fluorescent dye may specifically include a pyrazoline compound, and the black dye may specifically include liquid or powdered carbon black, a pyridine complex, an azo complex, a quinone compound, zirconium nitride, a titanium oxide, titanium nitride, black talc powder, a cobalt-chromium metal oxide, azine or phthalocyanine and the like.

The present invention further provides application of the resin composition in a semi-cured sheet, a laminate board, an insulating film, an insulating board, a circuit substrate and an electronic device. The application is specifically described as follows.

The present invention further provides a semi-cured sheet. The semi-cured sheet includes a reinforcing material and the resin composition. A method for preparing the semi-cured sheet includes: the resin composition is dissolved in a solvent to obtain a gel solution, the reinforcing material is impregnated in the gel solution, the impregnated reinforcing material is taken out, and is baked in an environment at 100-180° C. for 1-15 minutes; the semi-cured sheet can be obtained after drying.

The solvent is selected from at least one of acetone, butanone, toluene, methyl isobutyl ketone, N,N-dimethylformamide, N,N-dimethylacetamide, ethylene glycol methyl ether, propylene glycol methyl ether, benzene, toluene, xylene and cyclohexane.

The reinforcing material is selected from at least one of natural fiber, organic synthetic fiber, organic fabric and inorganic fabric. Preferably, the reinforcing material is glass fiber cloth; in the glass fiber cloth, preferably split cloth or flat cloth is used; and the glass fiber cloth is preferably E glass fiber cloth, S glass fiber cloth or Q glass fiber cloth.

In addition, when the reinforcing material is glass fiber cloth, the glass fiber cloth is subjected to chemical treatment with a coupling agent, so as to improve the interface binding between the resin composition and the glass fiber cloth. The coupling agent is preferably an epoxy silane coupling agent or an amino silane coupling agent, so as to provide good water resistance and heat resistance.

An example of the present invention further provides a laminate board. The laminate board includes one semi-cured sheet and metal foil arranged on at least one side surface of the semi-cured sheet; or the laminate board includes a composite sheet formed by superimposing a plurality of the semi-cured sheets and metal foil arranged on at least one side surface of the composite sheet.

The laminate board is prepared by the following method: one side surface or two side surfaces of one semi-cured sheet are coated with the metal foil, or at least two semi-cured sheets are superimposed to form a composite sheet, one side surface or two side surfaces of the composite sheet are coated with the metal foil, and then the metal foil laminate board can be obtained by hot pressing forming. The hot pressing is conducted under the following pressing conditions: pressing at 0.2-2 MPa and 150-250° C. for 2-4 hours.

Preferably, the metal foil is selected from copper foil or aluminum foil. The thickness of the metal foil is 5 microns, 8 microns, 12 microns, 18 microns, 35 microns or 70 microns.

An example of the present invention further provides an insulating board. The insulating board includes at least one semi-cured sheet.

An example of the present invention further provides an insulating film. The insulating film includes a carrier film and the resin composition coated on the carrier film, and the thermal index of the insulating film is significantly improved.

The insulating film is prepared by the following method: the resin composition is dissolved in a solvent to obtain a glue solution, the carrier film is coated with the glue solution, and the insulating film can be obtained after heating the carrier film coated with the glue solution for drying.

The solvent is selected from at least one of acetone, butanone, toluene, methyl isobutyl ketone, N,N-dimethylformamide, N,N-dimethylacetamide, ethylene glycol methyl ether, propylene glycol methyl ether, benzene, toluene, xylene and cyclohexane.

The carrier film is selected from at least one of a PET film, a PP film, a PE film and a PVC film.

An example of the present invention further provides a circuit substrate. The circuit substrate includes one or more of the semi-cured sheet, the laminate board, the insulating board and the insulating film.

An example of the present invention further provides an electronic device. The electronic device includes the circuit substrate. As the heat resistance of the circuit substrate is greatly improved, the safety of the electronic device is significantly improved.

The technical solutions of this application are further explained below in combination with some specific synthesis examples and comparative examples.

### Synthesis Example 1: Modified Bismaleimide Prepolymer Y1

100 g of a bismaleimide resin (BMI-2300 made by Daiwa Kagaku), 10 g of an amino organosilicone resin A (DOWSIL™ BY 16-853 with an amino equivalent of 450 g/mol) and an appropriate amount of an organic solvent were added to a beaker to carry out a reaction at 80° C. for 60 minutes, the temperature was raised to 100° C., 25 g of an amino organosilicone resin B (X-22-161A made by Shin-Etsu Chemical with an amino equivalent of 800 g/mol) was added to carry out the reaction continuously for 90 minutes, and then discharging was conducted to obtain a modified bismaleimide prepolymer Y1.

### Synthesis Example 2: Modified Bismaleimide Prepolymer Y2

100 g of a bismaleimide resin (MIR-3000 made by Nippon Kayaku), 5 g of an amino organosilicone resin A (KF-8010 made by Shin-Etsu Chemical with an amino equivalent of 430 g/mol) and an appropriate amount of an organic solvent were added to a beaker to carry out a reaction at 80° C. for 60 minutes, the temperature was raised to 100° C., 30 g of an amino organosilicone resin B (X-22-161A made by Shin-Etsu Chemical with an amino equivalent of 800 g/mol) was added to carry out the reaction continuously for 90 minutes, and then discharging was conducted to obtain a modified bismaleimide prepolymer Y2.

### Synthesis Example 3: Modified Bismaleimide Prepolymer Y3

100 g of a bismaleimide resin (BMI-2300 made by Daiwa Kagaku), 10 g of an amino organosilicone resin A (DOWSIL™ BY 16-853 with an amino equivalent of 450 g/mol), 1 g of aminophenol and an appropriate amount of an organic solvent were added to a beaker to carry out a reaction at 80° C. for 60 minutes, the temperature was raised to 100° C., 25 g of an amino organosilicone resin B (X-22-161A made by Shin-Etsu Chemical with an amino equivalent of 800 g/mol) was added to carry out the reaction continuously for 90 minutes, and then discharging was conducted to obtain a modified bismaleimide prepolymer Y3.

### Synthesis Example 4: Modified Bismaleimide Prepolymer Y4

100 g of a bismaleimide resin (BMI-2300 made by Nippon Kayaku), 10 g of an amino organosilicone resin A (KF-8010 made by Shin-Etsu Chemical with an amino equivalent of 430 g/mol), 1 g of aminophenol and an appropriate amount of an organic solvent were added to a beaker to carry out a reaction at 80° C. for 60 minutes, the temperature was raised to 100° C., 25 g of an amino organosilicone resin B (X-22-161B made by Shin-Etsu Chemical with an amino equivalent of 1,500 g/mol) was added to carry out the reaction continuously for 100 minutes, and then discharging was conducted to obtain a modified bismaleimide prepolymer Y4.

### Comparative Synthesis Example 1: Modified Bismaleimide Prepolymer Y5

100 g of a bismaleimide resin (BMI-2300 made by Daiwa Kasei), 35 g of an amino organosilicone resin A (DOWSIL™ BY 16-853 with an amino equivalent of 450 g/mol) and an appropriate amount of an organic solvent were added to a beaker to carry out a reaction at 100° C. for 120 minutes, and then discharging was conducted to obtain a modified bismaleimide prepolymer Y5.

### Comparative Synthesis Example 2: Modified Bismaleimide Prepolymer Y6

100 g of a bismaleimide resin (MIR-3000 made by Nippon Kayaku), 35 g of an amino organosilicone resin B (X-22-161A made by Shin-Etsu Chemical with an amino equivalent of 800 g/mol), 1 g of aminophenol and an appropriate amount of an organic solvent were added to a beaker to carry out a reaction at 100° C. for 120 minutes, and then discharging was conducted to obtain a modified bismaleimide prepolymer Y6.

According to the data in Table 1, a corresponding solid substance was weighed, and adjusted by a solvent to obtain a glue solution until the solid content was 60%, the glue solution was coated on E glass fiber cloth, and the E glass fiber cloth was impregnated and placed in an air blast drying oven for baking at 160° C. for 3-6 minutes to obtain a semi-cured sheet.

The semi-cured sheet was cut to a size of 300 mm×300 mm, a pair of electrolytic copper foils were placed on two sides of the semi-cured sheet respectively and then superimposed into a certain superposed configuration. Then, the semi-cured sheet was sent into a vacuum press for pressing to obtain a metal foil laminate board (or a copper clad laminate board). Specific performance test results are as shown in Table 2.

TABLE 1
Component table of resin compositions

| Component/ | Example | Example | Example | Example | Example | Comparative | Comparative |
|---|---|---|---|---|---|---|---|
| g | 1 | 2 | 3 | 4 | 5 | Example 1 | Example 2 |
| Prepolymer | 50 | — | 20 | — | — | — | — |
| Y1 | | | | | | | |
| Prepolymer | — | 60 | 20 | — | — | — | — |
| Y2 | | | | | | | |
| Prepolymer | — | — | — | 50 | — | — | — |
| Y3 | | | | | | | |
| Prepolymer | — | — | — | — | 50 | — | — |
| Y4 | | | | | | | |
| Prepolymer | — | — | — | — | — | 50 | — |
| Y5 | | | | | | | |
| Prepolymer | — | — | — | — | — | — | 60 |
| Y6 | | | | | | | |
| Bisphenol A | 20 | — | 35 | 20 | 20 | 20 | — |
| cyanate | | | | | | | |
| resin | | | | | | | |
| Phenolic | — | 30 | — | — | — | — | 30 |
| cyanate | | | | | | | |
| resin | | | | | | | |
| Catalyst | 0.1 | 0.1 | 0.1 | 0.1 | 0.1 | 0.1 | 0.1 |
| Elastomer | 10 | 10 | 10 | 10 | 10 | 10 | 10 |
| Styrene- | | | | | | | |
| butadiene | | | | | | | |
| Silica filler | 122 | 122 | 122 | 122 | 122 | 122 | 122 |

TABLE 2
Performance table

| | Example | Example | Example | Example | Example | Comparative | Comparative |
|---|---|---|---|---|---|---|---|
| Performance | 1 | 2 | 3 | 4 | 5 | Example 1 | Example 2 |
| Tg/° C. | 332 | 341 | 328 | 335 | 320 | 310 | 305 |
| CTE (X-Y, | 6 | 5 | 6 | 6 | 8 | 9 | 11 |
| α1)/° C.⁻¹ | | | | | | | |
| Water | 0.40 | 0.32 | 0.35 | 0.38 | 0.46 | 0.51 | 0.48 |
| absorption/% | | | | | | | |
| Secondary | OK | OK | OK | OK | OK | White cracks | Few white |
| apparent | | | | | | dispersed in | cracks |
| defect of | | | | | | board | dispersed in |
| board | | | | | | | board |

Performances of all the semi-cured sheets and copper clad laminate boards prepared in Examples 1-5 and Comparative Examples 1-2 were tested.

(1) Glass transition temperature: the glass transition temperature was determined by DMA (thermomechanical analysis) at a heating rate of 10° C./min.

(2) Determination of PCT 2 HR water absorption: 3 samples with a size of 10 cm×10 cm and a thickness of 0.40 mm and with the metal foil removed from two surfaces were dried at 100° C. for 2 hours, and weighed and recorded as W1, then the samples were treated in a pressure cooker test machine at 121° C. under 2 atmospheres for 2 hours, and weighed and recorded as W2, and the water absorption was determined as (W2−W1)/W1×100%.

(3) Determination of X/Y coefficient of thermal expansion (CTE): the X/Y coefficient of thermal expansion was determined by TMA (thermomechanical analysis) at a heating rate of 10° C./min in a test temperature range of 30-100° C.

(4) Secondary apparent defect: the secondary apparent defect was determined by a standard method specified in IPC-TM-650, and whether a base material has dry patterns, white cracks and other defects is determined by a visual method or a slice method.

According to the above experimental data, it can be seen that the products in Examples 1-3 have excellent performances including high Tg value, low water absorption, low CTE value and good apparent mass, where the product in Example 1 has higher Tg value and lower CTE value than the product in Comparative Example 1, and the product in Example 2 has higher Tg value and lower CTE value than the product in Comparative Example 2.

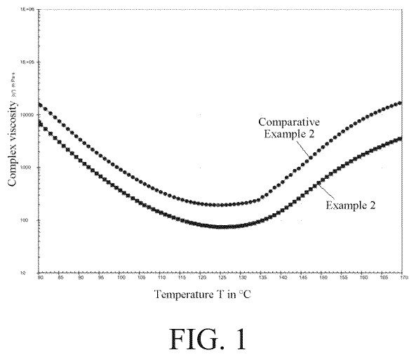

In addition, according to the rheological curves of Comparative Example 2 and Example 2 in FIG. 1, it can be seen that the product in Example 2 has a wider rheological window and lower minimum melt viscosity, indicating that the resin reaction is slow, and convenience is provided for controlling the processability.

It is to be understood that although this specification has been described through embodiments, each embodiment does not contain only an independent technical solution, and the specification is described in this way merely for the sake of clarity. The specification should be considered as a whole by persons skilled in the art, and the technical solutions in various embodiments may be appropriately combined to form other embodiments that can be understood by persons skilled in the art.

A series of detailed descriptions listed above are merely specific descriptions of the feasible examples of the present invention, and are not intended to limit the scope of the protection of the present invention. Any equivalent examples or changes made without departing from the technical spirit of the present invention shall be included in the scope of the protection of the present invention.

1. A modified bismaleimide prepolymer, wherein the modified bismaleimide prepolymer is obtained by a reaction of a bismaleimide compound with an amino organosilicone resin A and an amino organosilicone resin B, the amino equivalent (Ea_{A}) of the amino organosilicone resin A is different from the amino equivalent (Ea_{B}) of the amino organosilicone resin B, and the ratio of the total mass of the amino organosilicone resin A and the amino organosilicone resin B to the mass of the bismaleimide compound is (5-80):100.

2. The modified bismaleimide prepolymer according to claim 1, wherein the ratio of the total mass of the amino organosilicone resin A and the amino organosilicone resin B to the mass of the bismaleimide compound is (20-50):100.

3. The modified bismaleimide prepolymer according to claim 1, wherein the mass ratio of the amino organosilicone resin A to the amino organosilicone resin B is 1:(2-30).

4. The modified bismaleimide prepolymer according to claim 1, wherein both the amino organosilicone resin A and the amino organosilicone resin B have the following structure: 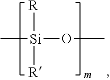
wherein both R and R′ are C1-C5 alkyl, and m is an integer ranging from 1 to 30.

5. The modified bismaleimide prepolymer according to claim 1, wherein a side chain of the amino organosilicone resin A and/or the amino organosilicone resin B contains at least one amino.

6. The modified bismaleimide prepolymer according to claim 1, wherein a terminal end of the amino organosilicone resin A and/or the amino organosilicone resin B contains at least one amino.

7. A resin composition, wherein the resin composition comprises, by weight, the following components:
(a) 30-100 parts of a modified bismaleimide prepolymer,
(b) 3-50 parts of a cyanate resin, and
(c) 5-60 parts of an elastomer,
wherein the modified bismaleimide prepolymer is the modified bismaleimide prepolymer according to claim 1.

8. The resin composition according to claim 7, wherein the cyanate resin is selected from one or more of a bisphenol A cyanate resin, a bisphenol F cyanate resin, a bisphenol S cyanate resin, a bisphenol E cyanate resin, a bisphenol M cyanate resin, a cyanate resin containing a double bond, a phosphorus-containing cyanate resin, a phenolic cyanate resin, a biphenyl cyanate resin, a naphthalene ring cyanate resin and a dicyclopentadiene cyanate resin.

9. The resin composition according to claim 8, wherein the cyanate resin is a naphthalene ring cyanate resin or/and a phenolic cyanate resin having the following structure: 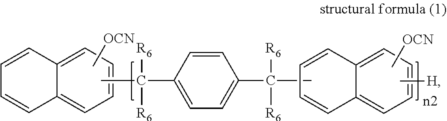
wherein R₆ is hydrogen, methyl or ethyl, and n₂ is an integer ranging from 1 to 10;
or 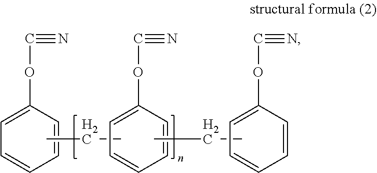
wherein n is an integer ranging from 1 to 10.

10. The resin composition according to claim 7, wherein the elastomer is selected from at least one of a styrene elastomer, a methacrylate elastomer and an organosilicone elastomer.

11. The resin composition according to claim 7, wherein the resin composition further comprises a silane coupling agent and a dispersing agent.

12. The resin composition according to claim 11, wherein the silane coupling agent is an epoxy silane coupling agent, the dispersing agent is a phosphate dispersing agent and/or a modified polyurethane dispersing agent, and the weight ratio of the silane coupling agent to the dispersing agent is 2:1 to 10:1.

13. Application of the resin composition according to claim 7 in a semi-cured sheet, a laminate board, an insulating film, an insulating board, a copper clad laminate, a circuit substrate and an electronic device.

14. The modified bismaleimide prepolymer according to claim 2, wherein the mass ratio of the amino organosilicone resin A to the amino organosilicone resin B is 1:(2-30).
